(19) United States
(12) Patent Application Publication
(10) Pub. No.: US 2021/0105915 A1
(43) Pub. Date: Apr. 8, 2021

(54) ELECTRICAL CONNECTOR

(71) Applicant: Dongguan Luxshare Technologies Co., Ltd, Dongguan City (CN)

(72) Inventors: XiaoKai WANG, Dongguan City (CN); Zhen LUO, Dongguan City (CN); XiaoPing WU, Dongguan City (CN); BaiYu DUAN, Dongguan City (CN)

(73) Assignee: Dongguan Luxshare Technologies Co., Ltd, Dongguan City (CN)

(21) Appl. No.: 16/749,217

(22) Filed: Jan. 22, 2020

(30) Foreign Application Priority Data
Oct. 8, 2019 (CN) 201921669771.4

(51) Int. Cl. H05K 7/20; H05K 1/02; H01R 12/71

(52) U.S. Cl. CPC H05K 7/20418; H05K 1/0203; H05K 2201/10416; H01R 12/712; H05K 7/20445

(57) ABSTRACT

The present disclosure provides an electrical connector comprising an electrical connector housing and a cooling module. The electrical connector housing comprises an upper surface, a lower surface, and two opposite sidewalls. The cooling module is disposed on the upper surface of the electrical connector housing. The cooling module comprises a first heat sink and a second heat sink connected to the first heat sink. A type of the first heat sink is different from a type of the second heat sink. The flexibility of the arrangement of the cooling modules of the electrical connectors can be enhanced by disposing multiple heat sinks in various types on the electrical connector housing. The cooperation between multiple heat sinks could be effectively coordinated according to different requirements.

### CROSS REFERENCE TO RELATED APPLICATION

This application claims the priority benefit of Chinese Patent Application Serial Number 201921669771.4, filed on Oct. 8, 2019, the full disclosure of which is incorporated herein by reference.

### BACKGROUND

### Technical Field

The present disclosure relates to the technical field of electrical connector, and more particularly to an electrical connector.

### Related Art

Electrical connectors are usually equipped with heat sinks, which dissipating the heat generated during the operation of electrical connectors to the outside, to prevent the operation of the connectors from being affected by the heat accumulation from accumulating therein. The conventional electrical connectors mostly are provided with single type finned heat sinks, which is structurally non-adjustable as all the cooling fins are integrated into a one-piece heat sink. Considering different cooling requirements, such arrangement of the cooling fins is inflexible.

### SUMMARY

The embodiments of the present disclosure provide an electrical connector intended to solve the issue of the inflexibility of the single type finned heat sinks of conventional electrical connectors considering different cooling requirements.

The present disclosure provides an electrical connector comprising: an electrical connector housing comprising an upper surface, a lower surface, and two opposite sidewalls; and a cooling module disposed on the upper surface of the electrical connector housing. The cooling module comprises a first heat sink and a second heat sink connected to the first heat sink. A type of the first heat sink is different from a type of the second heat sink.

The embodiments of the present disclosure could enhance the flexibility of the arrangement of the cooling modules of the electrical connectors by disposing multiple heat sinks in various types of the electrical connector housing. The cooperation between multiple heat sinks could be effectively coordinated according to different requirements.

It should be understood, however, that this summary may not contain all aspects and embodiments of the present invention, that this summary is not meant to be limiting or restrictive in any manner, and that the invention as disclosed herein will be understood by one of ordinary skill in the art to encompass obvious improvements and modifications thereto.

### BRIEF DESCRIPTION OF THE DRAWINGS

The features of the exemplary embodiments believed to be novel and the elements and/or the steps characteristic of the exemplary embodiments are set forth with particularity in the appended claims. The Figures are for illustration purposes only and are not drawn to scale. The exemplary embodiments, both as to organization and method of operation, may best be understood by reference to the detailed description which follows taken in conjunction with the accompanying drawings in which:

FIG. 1 is a perspective view of an electrical connector of the first embodiment of the present disclosure;

FIG. 2 is another perspective view of an electrical connector of the first embodiment of the present disclosure;

FIG. 3 is an exploded view of an electrical connector of the first embodiment of the present disclosure;

FIG. 4 is a cross-sectional view of a cooling module of the first embodiment of the present disclosure;

FIG. 5 is an exploded view of a cooling module of the first embodiment of the present disclosure;

FIG. 6 is a perspective view of an electrical connector of the second embodiment of the present disclosure;

FIG. 7 a cross-sectional view of an electrical connector of the second embodiment of the present disclosure;

FIG. 8 is a schematic diagram of a second heat sink of the third embodiment of the present disclosure; and

FIG. 9 is a schematic diagram of a second heat sink of the fourth embodiment of the present disclosure.

### DETAILED DESCRIPTION OF THE EMBODIMENTS

The present invention will now be described more fully hereinafter with reference to the accompanying drawings, in which exemplary embodiments of the invention are shown. This present invention may, however, be embodied in many different forms and should not be construed as limited to the embodiments set forth herein. Rather, these embodiments are provided so that this present invention will be thorough and complete, and will fully convey the scope of the present invention to those skilled in the art.

Certain terms are used throughout the description and following claims to refer to particular components. As one skilled in the art will appreciate, manufacturers may refer to a component by different names. This document does not intend to distinguish between components that differ in name but function. In the following description and in the claims, the terms “include/including” and “comprise/comprising” are used in an open-ended fashion, and thus should be interpreted as “including but not limited to”. “Substantial/substantially” means, within an acceptable error range, the person skilled in the art may solve the technical problem in a certain error range to achieve the basic technical effect.

The following description is of the best-contemplated mode of carrying out the invention. This description is made for the purpose of illustration of the general principles of the invention and should not be taken in a limiting sense. The scope of the invention is best determined by reference to the appended claims.

Moreover, the terms “include”, “contain”, and any variation thereof are intended to cover a non-exclusive inclusion. Therefore, a process, method, object, or device that comprises a series of elements not only include these elements, but also comprises other elements not specified expressly, or may include inherent elements of the process, method, object, or device. If no more limitations are made, an element limited by “include a/an . . . ” does not exclude other same elements existing in the process, the method, the article, or the device which comprises the element.

In the following embodiment, the same reference numerals are used to refer to the same or similar elements throughout the invention.

In the following embodiments, the same or similar elements will be indicated by the same reference numerals.

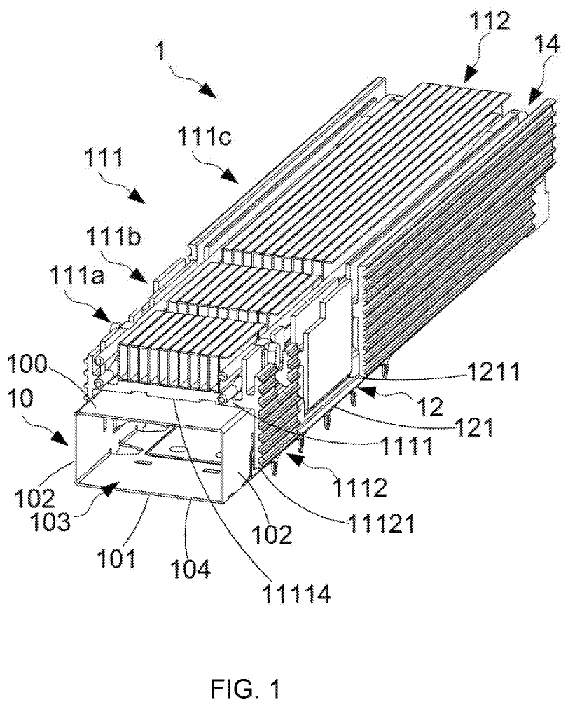

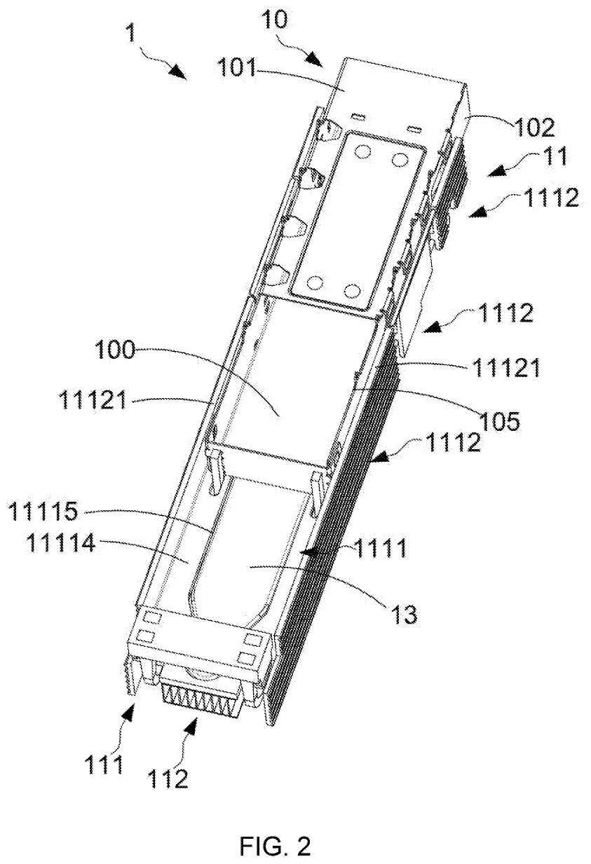

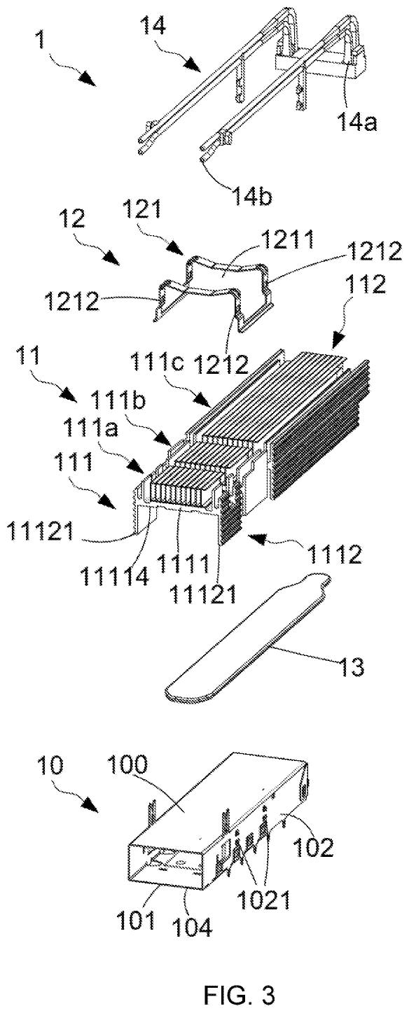

FIG. 1, FIG. 2 and FIG. 3 are perspective views and an exploded view of an electrical connector of the first embodiment of the present disclosure. As shown in the figure, the electrical connector 1 of this embodiment comprises an electrical connector body (not shown), an electrical connector housing 10 and a cooling module 11. The electrical connector housing 10 comprises an upper surface 100, a lower surface 101, two opposite sidewalls 102, an accommodating space 103, a first opening 104, and a second opening 105. The first opening 104 is disposed at one end of the upper surface 100, the lower surface 101 and the two side walls 102. The second opening 105 is disposed on the lower surface 101 and is far from the first opening 104. This means that the end of the electrical connector housing 10 opposite the first opening 104 is a closed-end. The electrical connector body is disposed in the accommodating space 103. The interface end of each electrical connector body 10 corresponds to the first opening 104. The electrical connecting end of each electrical connector body 10 corresponds to the second opening 105. In this embodiment, the second opening 105 is disposed on the lower surface 101 of the electrical connector housing 10 as the electrical connector 1 is a horizontal type electrical connector. The electrical connector 1 could be a vertical type electrical connector, making the second opening 105 to be disposed on one end of the electrical connector housing 10 opposite to the first opening 104.

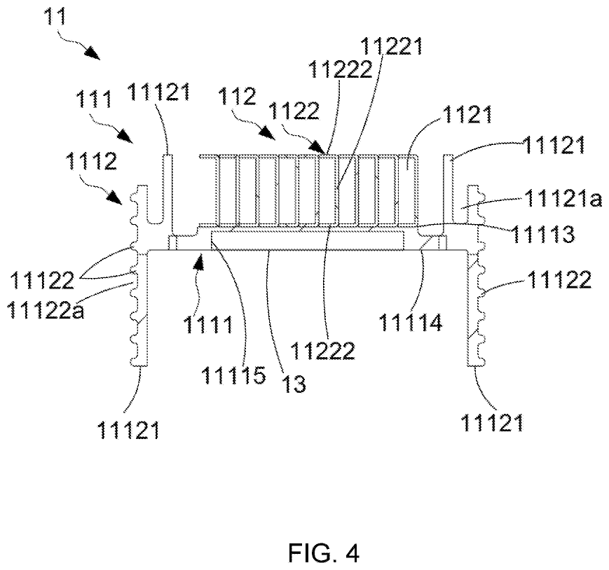

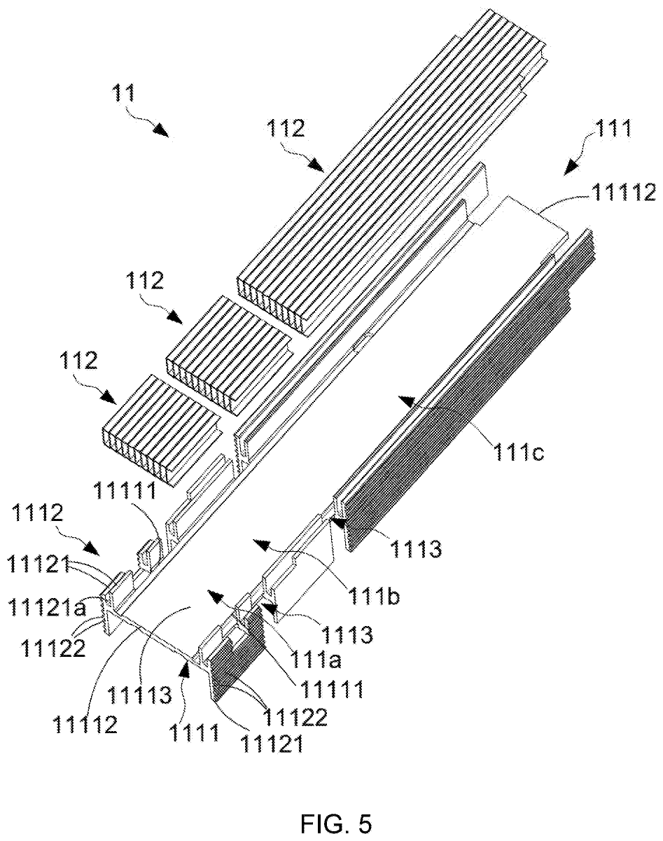

FIG. 4 and FIG. 5 are a cross-sectional view and an exploded view of a cooling module of the first embodiment of the present disclosure. As shown in the figure, the cooling module 11 is disposed on the upper surface 100 of the casing 10. The cooling module 11 comprises first heat sinks 111 and second heat sink 112. The first heat sink 111 and the second heat sink 112 are different types of heat sinks, which are combining into the cooling module 11. In this embodiment, the first heat sink 111 is a finned heat sink, and the second heat sink is a stacked heat sink. The second heat sink 112 is disposed on the first heat sink 111. The second heat sink 112 is connected to the first heat sink 111 by welding or engaging.

The first heat sink 111 of this embodiment comprises a support base 1111 and two cooling parts 1112. The support base 1111 comprises two opposite first side edges 11111 and two second side edges 11112. The two first side edges 11111 are parallel to the sidewalls 102 of the electrical connector housing 10. The two second side edges 11112 are perpendicular to the sidewalls 102 of the electrical connector housing 10. The support base 1111 further comprises a first surface 11113 and a second surface 11114. The first surface 11113 is opposite to the second surface 11114. Two cooling parts 1112 are respectively disposed on the two first side edges 11111 of the support base 1111, so that the first heat sink 111 is formed into an H-shape. Each cooling part 1112 comprises a plurality of vertical cooling fins 11121 disposed at intervals. The plurality of vertical cooling fins 11121 is connected together and extend along the first side edge 11111 of the support base 1111. A vertical cooling channel 11121a is provided between two adjacent vertical cooling fins 1112 parallel to the first side edges 11111 of the support base 1111. Two ends of at least one of the plurality of vertical cooling fins 11121 of each cooling part 1112 are respectively away from the first surface 11113 and the second surface 11114 of the support base 1111. In this way, the arrangement that the two cooling parts are disposed at the two sides of the support base forms an H-shape. In this embodiment, two ends of the outermost vertical cooling fins 11121 of each cooling part 1112 are respectively away from the first surface 11113 and the second surface 11114 of the support base 1111.

In another embodiment, a plurality of horizontal cooling fins 11122 is disposed on the surface of the outermost vertical cooling fins 11121 away from the support base 1111. The plurality of horizontal cooling fins 11122 are disposed at intervals and extend along the first side edges 11111 of the support base 1111. A horizontal cooling channel 11122a is provided between two adjacent horizontal cooling fins 11122. The horizontal cooling channel 11122a is parallel to the first side edges 11111 of the support base 1111. It indicates that the vertical cooling channels 11121a and the horizontal cooling channels 11122a extend in the same direction along the first side edges 11111 of the support base 1111.

The first heat sink 111 of this embodiment is disposed on the electrical connector housing 10. The second surface 11114 of the support base 1111 of the first heat sink 111 is in contact with the upper surface 100 of the electrical connector housing 10. One of the plurality of vertical cooling fins 11121 of each cooling part 1112 of the first heat sink 111 is in contact with the sidewall 102 of the electrical connector housing 10. In this way, the heat generated by the electrical connector 1 can be quickly transmitted from the plurality of vertical cooling channels 11121a between a plurality of vertical cooling fins 11121 and the plurality of horizontal cooling channels 11122a between a plurality of horizontal cooling fins 11122 to the outside. In this embodiment, the second surface 11114 of the support base 1111 may not partially or fully contact with the upper surface 100 of the electrical connector housing 10. The vertical cooling fins 11121 of the cooling part 1112 may not partially or fully contact with the sidewall 102 of the electrical connector housing 10.

The first heat sink 111 of this embodiment is secured to the electrical connector housing 10 through a securing part 12. Therefore, the first heat sink 111 comprises two securing grooves 1113 dividing the first heat sink 111 into a first section 111a, a second section 111b, and a third section 111c. The second heat sink 112 is disposed in the first section 111a, the second section 111b, and the third section 111c. It indicates that two adjacent second heat sinks 112 are respectively disposed on two sides of the corresponding securing grooves 1113. The second heat sink 112 is disposed on the first surface 11113 of the support base 1111. The first surface 11113 is a flat surface to facilitate the disposing of the second heat sinks 112.

The securing component 12 of this embodiment is a single U-shaped securing part 121 comprising a hollow part 1211. The cooling part 1112 of the first heat sink 111 and the second heat sink 112 disposed in the second section 111b would enter the hollow part 1211 of the U-shaped securing part 121 while the U-shaped securing part 121 is disposed in the two securing grooves 1113. Two ends of the U-shaped securing part 121 are secured on the two sidewalls 102 of the electrical connector housing 10. Each U-shaped securing part 121 abuts against the first surface 11113 of the support base 1111 of the first heat sink 111 to secure the cooling module 11 onto the electric connector housing 10.

The U-shaped securing part 121 could be elastic. Two ends of the U-shaped securing part 121 could clamp the electrical connector housing 10 by its own elastic force, securing the U-shaped securing part 121 on the electrical connector housing 10. Or, the two ends of the U-shaped securing part 121 are secured to the sidewalls 102 of the electrical connector housing 10 by engaging components. In this embodiment, the two sidewalls 102 of the electrical connector housing 10 are respectively provided with first engaging parts 1021. Second engaging parts 1212 are respectively disposed at two ends of the U-shaped securing part 121. The second engaging part 1212 is disposed on the first engaging part 1021 so that two ends of the U-shaped securing part 121 are secured on the two sidewalls 102 of the electrical connector housing 10. In this embodiment, the first engaging part 1021 is a protruding, and the second engaging part 1212 is a hole. The first engaging part 1021 could be a hole, and the second engaging part 1212 could be a protruding.

In another embodiment, the arrangement of multiple horizontal cooling fins 11122 is omitted among the two cooling parts 1112 disposed between the two securing grooves 1113 (in the second section 111b). In this way, the U-shaped securing part 121 can be easily installed on the electrical connector housing 10 without being interfered by the horizontal cooling fins 11122. The above securing component 12 is only one embodiment of the present disclosure. In another embodiment, the securing component 12 comprises two U-shaped securing parts 121, and each U-shaped securing part 121 does not comprise a hollow part 1211. Each U-shaped securing part 121 is directly disposed in the corresponding securing groove 1113. Two ends of the U-shaped securing part 121 are secured on the two sidewalls 102 of the electrical connector housing 10. If such a securing component 12 is used, a plurality of horizontal cooling fins 11122 of the cooling part 1112 disposed in the second section 111b can be maintained.

The second heat sink 112 of this embodiment comprises a plurality of U-shaped cooling fins 1122 stacked together. The plurality of U-shaped cooling fins 1122 is secured by welding and engaging, so that the plurality of U-shaped cooling fins 1122 is integrated to prevent themselves from being falling apart. Therefore, the second heat sink 112 is assembled by a plurality of U-shaped cooling fins 1122, which means that the second heat sink 112 is adjustable, for example, to adjust the number or size of the U-shaped cooling fins 1122.

Each U-shaped cooling fin 1122 comprises a first plate 11221 and two opposite second plates 11222 disposed on two sides of the first plate 11221. Each U-shaped cooling fin 1122 is a one-piece element, which is formed by the stamping process. The U-shaped cooling fins 1122 stacked together. The two second plates 11222 of each U-shaped cooling fin 1122 are stacked on the first plate 11221 of the adjacent U-shaped cooling fin 1122, making the plurality of second plates 11222 on the same side to be disposed on the same physical plane. A cooling channel 1121 is provided between the two first plates 11221 of two adjacent U-shaped cooling fins 1122. While the second heat sink 112 is disposed on the first heat sink 111, the plurality of second plates 11222 connected to the second heat sink 112 is disposed on the first surface 11113 of the support base 1111 of the first heat sink 111. The plurality of first plates 11221 of the second heat sink 112 is perpendicular to the first surface 11113 of the support base 1111.

The dimensions or number of the cooling channels 1121 of the second heat sink 112 in the above embodiment are adjustable. The number of cooling channels 1121 of the second heat sink 112 can be adjusted by increasing or decreasing the number of U-shaped cooling fins 1122. To adjust the dimensions of the cooling channels 1121 of the second heat sink 112, select a U-shaped cooling fin 1122 having a smaller distance between one end of the second plate 11222 away from the first plate 11221 and one end where the second plate 11222 is connected to the first plate 11221 to decrease the width of each cooling channel 1121, and select a U-shaped cooling fin 1122 having a greater distance between one end of the second plate 11222 away from the first plate 11221 and one end where the second plate 11222 is connected to the first plate 11221 to increase the width of each cooling channel 1121 as the width of each cooling channel 1121 is determined by the corresponding distance between one end of the second plate 11222 of the U-shaped cooling fin 1122 away from the first plate 11221 and one end where the second plate 11222 is connected to the first plate 11221.

The height of each cooling channel 1121 is determined by the distance between the two second plates 11222 of the corresponding U-shaped cooling fins 1122. To reduce the height of each cooling channel 1121, select a U-shaped cooling fin 1122 having a smaller distance between the two second plates 11222; to increase the height of each cooling channel 1121, select a U-shaped cooling fin 1122 having a greater distance between the two second plates 11222.

The length of each cooling channel 1121 is determined by the length of the first plate 11221 of the corresponding U-shaped cooling fin 1122. To reduce the length of each cooling channel 1121, select a U-shaped cooling fin 1122 having a smaller length of the first plate 11221; to increase the length of each cooling channel 1121, select a U-shaped cooling fin 1122 having a greater length of the first plate 11221.

Thus, the dimensions or quantity of the cooling channels 1121 of the second heat sink 112 could be adjusted according to requirements making the cooling module 11 satisfying different conditions. In this embodiment, the cooling channel 1121 of the second heat sink 112 in the first section 111a has the shortest length; the cooling channel 1121 of the second heat sink 112 in the third section 111c has the longest length. This indicates that the length of the first plate 11221 of the U-shaped cooling fin 1122 of the second heat sink 112 in the third section 111c is longer than the length of the first flat plate 11221 of the U-shaped cooling fins 1122 in the first section 111a and the second section 111b; the length of the first plate 11221 of the U-shaped cooling fin 1122 of the second heat sink 112 in the second section 111b is longer than the length of the first plate 11221 of the U-shaped cooling fin 1122 in the first section 111a. In addition, the height of the cooling channel 1121 of the second heat sink 112 in the third section 111c is greater than the height of the cooling channel 1121 of the second heat sink 112 in the first section 111a and the second section 111b; the height of the cooling channel 1121 of the second heat sink 112 in the first section 111a is equal to the height of the cooling channel 1121 of the second heat sink 112 in the second section 111b. This indicates that the distance between the two second plates 11222 of the U-shaped cooling fins 1122 of the second heat sink 112 in the third section 111c is greater than the distance between the two second plates 11222 of the U-shaped cooling fins 1122 of the second heat sink 112 in the first section 111a and the second section 111b; the distance between two second plates 11222 of the U-shaped cooling fin 1122 of the second heat sink 112 in the second section 111b is equal to the distance between two second plates 11222 of the U-shaped cooling fin 1122 of the second heat sink 112 in the first section 111a. The widths of the cooling channels 1121 of all the second heat sinks 112 in this embodiment are all identical, showing that among the second heat sinks 112 in the first section 111a, the second section 111b and the third section 111c, the distance between one end of the second plate 11222 of each U-shaped cooling fin 1122 away from the first plate 11221 and one end of the second plate 11222 connected to the first plate 11221 are identical.

The above description illustrates that the cooling channels 1121 of each second heat sink 112 in different sections have different dimensions, and shows that the dimension of cooling channel 1121 of each second heat sink 112 is adjustable. In addition, the dimension of each cooling channel 1121 of the second heat sink 112 in a single section may also be different. For example, in this embodiment, the length of the middle cooling channel 1121 of the second heat sink 112 in the third section 111c is longer than the length of the cooling channels 1121 on two sides of the second heat sink 112 in the third section 111c. This also indicates that the length of the first flat plate 11221 of the middle U-shaped cooling fin 1122 of the second heat sink 112 in the third section 111c is longer than the length of the first flat plate 11221 of the U-shaped cooling fins 1122 on two sides of the second heat sink 112 in the third section 111c.

The electrical connector 1 of this embodiment further comprises a thermal conductive component 13 disposed between the upper surface 100 of the electrical connector housing 10 and the second surface 11114 of the support base 1111 of the first heat sink 111. The electrical connector 1 of this embodiment accelerates the conduction of the heat generated by the electrical connector housing 10 to the cooling module 11 through the thermal conductive component 13, and the heat is transmitted to the outside through the cooling module 11, resulting in an excellent cooling outcome for the electrical connector 1 of this embodiment. An accommodating recess 11115 is provided on the second surface 11114 of the support base 1111 in this embodiment. The thermal conductive component 13 is disposed in the accommodating recess 11115 to increase the contact area between the thermal conductive component 13 and the first heat sink 111. Therefore, the heat generated by the electrical connector housing 10 is rapidly conducted to the cooling module 11.

The electrical connector 1 of this embodiment further comprises light pipes 14 disposed on the first surface 11113 of the support base 1111 of the first heat sink 111. The light pipe 14 is disposed between the cooling part 1112 of the first heat sink 111 and the second heat sink 112. The light pipe 14 comprises an entrance 14a and an exit 14b. As the electrical connector 1 of this embodiment is a horizontal type electrical connector, the entrance 14a is on one side of the second opening 105, and the exit 14b is on one side of the first opening 104. When the electrical connector 1 of this embodiment is disposed on a circuit board, the entrance 14a of the light pipe 14 corresponds to a light-emitting component of the circuit board. The light emitted from the light-emitting component enters the entrance 14a, and the light passes through the light pipe 14 and exits the exit 14b to display the state of the electrical connector 1.

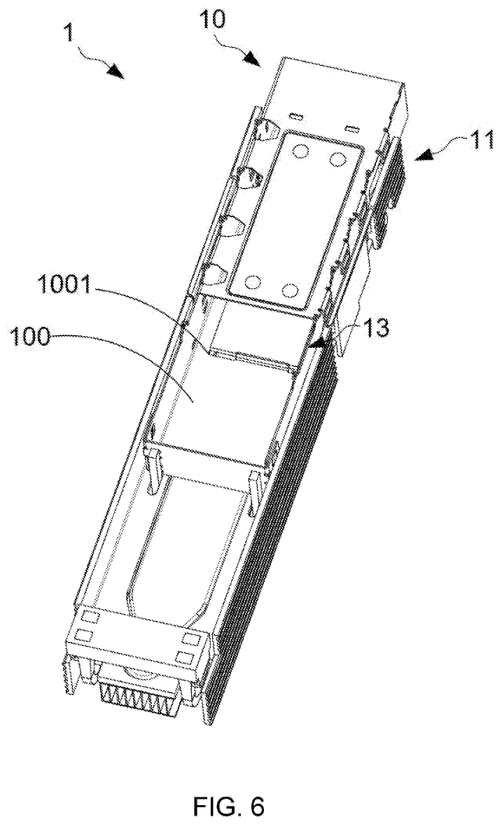

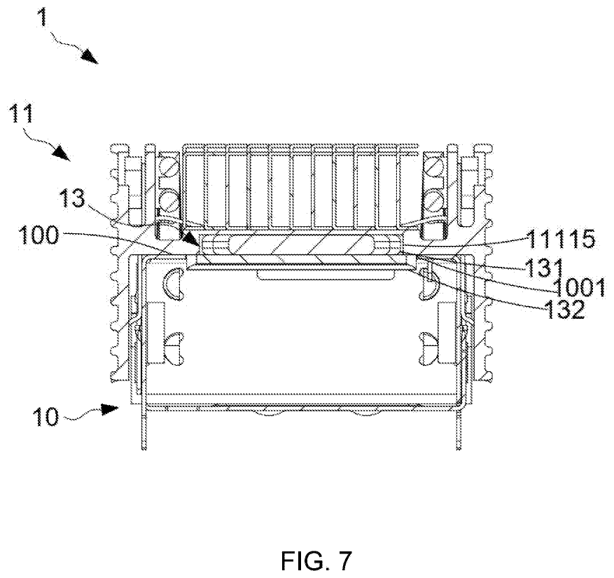

FIG. 6 and FIG. 7 are a perspective view and a cross-sectional view of an electrical connector of the second embodiment of the present disclosure. The electrical connector 1 of this embodiment is different from that of the first embodiment in that the upper surface 100 of the electrical connector housing 10 of this embodiment comprises an opening 1001. The thermal conductive component 13 could extend into the electrical connector housing 10 through the opening 1001, to contact with the electrical connector body in the electrical connector housing 10. That is, the thermal conductive component 13 can directly contact the heat source of the electrical connector 1, resulting direct conduction of the heat of the electrical connector 1 to be transmitted to the cooling module 11 from the thermal conductive component 13, which greatly increase the cooling performance of the electrical connector 1. The thermal conductive component 13 of this embodiment comprises a first thermal conductive part 131 and a second thermal conductive part 132. The first thermal conductive part 131 is disposed in the accommodating recess 11115 of the support base 1111. The second thermal conductive part 132 is disposed on a surface of the first thermal conductive part 131 away from the support base 1111, and to be disposed in the electrical connector housing 10 through the opening 1001. The second thermal conductive part 132 transmits the heat to the first thermal conductive part 131 by direct contact with the heat generated by the electrical connector 1. The heat would be then transmitted to the cooling module 11 by the thermal conductive part 131, and finally to the outside of the device by the cooling module 11.

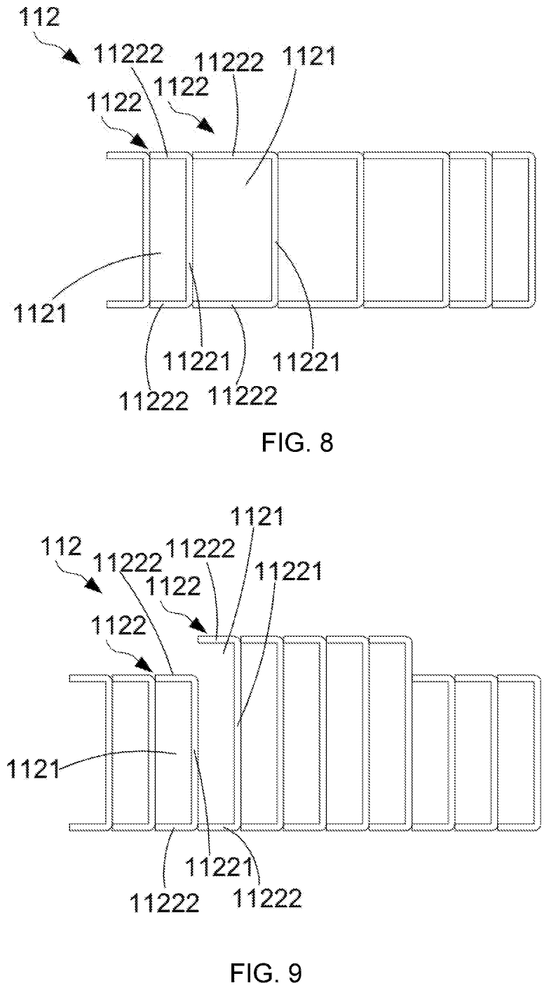

FIG. 8 is a schematic diagram of a second heat sink of the third embodiment of the present disclosure. A shown in the figure, the cooling channels 1121 of the second heat sink 112 are provided with multiple dimensions. The width of the plurality of cooling channels 1121 in the middle of the second heat sink 112 is identical. The width of the plurality of cooling channels 1121 on two sides of the second heat sink 112 is identical. The width of the plurality of cooling channels 1121 in the middle of the second heat sink 112 is greater than the width of the plurality of cooling channels 1121 on two sides of the second heat sink 112. This indicates that the distance between one end of the second plate 11222 of each U-shaped cooling fin 1122 in the middle of the second heat sink 112 away from the first plate 21221 and one end where the second plate 11222 is connected to the first plate 11221 is greater than the distance between one end of the second flat plate 11222 of each U-shaped cooling fin 1122 on two sides of the second heat sink 112 away from the first plate 21221 and one end where the second plate 11222 is connected to the first plate 11221.

FIG. 9 is a schematic diagram of a second heat sink of the fourth embodiment of the present disclosure. As shown in the figure, the heights of the plurality of cooling channels 1121 in the middle of the second heat sink 112 are identical. The heights of the plurality of cooling channels 1121 on two sides of the second heat sink 112 are identical. The height of the plurality of cooling channels 1121 in the middle of the second heat sink 112 is greater than the height of the plurality of cooling channels 1121 on two sides of the second heat sink 112. This indicates that the distance between the two second plates 11222 of each U-shaped cooling fin 1122 in the middle of the second heat sink 112 is larger than the distance between two second plates 11222 of each U-shaped heat sink fin 1122 on two sides of the second heat sink 112.

It can be known from the above that the second heat sink 112 can be configured to present cooling channels 1121 in various dimensions by combining a plurality of U-shaped cooling fins 1122 of different sizes. It indicates that the plurality of U-shaped cooling fins 1122 of different sizes can be combined to form an appropriate second heat sink 112 according to requirements.

In summary, the present disclosure provides an electrical connector by providing a plurality of heat sinks in various types on the electrical connector housing, particularly the combination of the stack type and the finned heat sinks. The stack type heat sink is a combination of a plurality of U-shaped cooling fins. The dimensions of the cooling channels of the stack type heat sinks can be adjusted by adjusting the quantity or size of the U-shaped cooling fins. In this way, the flexibility of the arrangement of the cooling modules of the electrical connectors could be enhanced. The cooperation between multiple heat sinks could be effectively coordinated according to different requirements.

It is to be understood that the term “comprises”, “comprising”, or any other variants thereof, is intended to encompass a non-exclusive inclusion, such that a process, method, article, or device of a series of elements not only include those elements but also comprises other elements that are not explicitly listed, or elements that are inherent to such a process, method, article, or device. An element defined by the phrase “comprising a . . . ” does not exclude the presence of the same element in the process, method, article, or device that comprises the element.

Although the present invention has been explained in relation to its preferred embodiment, it does not intend to limit the present invention. It will be apparent to those skilled in the art having regard to this present invention that other modifications of the exemplary embodiments beyond those embodiments specifically described here may be made without departing from the spirit of the invention. Accordingly, such modifications are considered within the scope of the invention as limited solely by the appended claims.

1. An electrical connector, comprising:
an electrical connector housing comprising an upper surface, a lower surface, and two opposite sidewalls; and
a cooling module disposed on the upper surface of the electrical connector housing; the cooling module comprises a first heat sink and a second heat sink connected to the first heat sink; a type of the first heat sink is different from a type of the second heat sink.

2. The electrical connector according to claim 1, wherein the second heat sink is connected to the first heat sink by welding or engaging.

3. The electrical connector according to claim 1, wherein the first heat sinks are finned heat sinks; the second heat sink is a stacked heat sink.

4. The electrical connector according to claim 3, wherein the first heat sink comprises a support base and two cooling parts; the arrangement that the two cooling parts are disposed at the two sides of the support base forms an H-shape.

5. The electrical connector according to claim 4, wherein each cooling part comprises a plurality of vertical cooling fins disposed at intervals; the plurality of vertical cooling fins are connected together; a plurality of vertical cooling channels exists between the plurality of the vertical cooling fins.

6. The electrical connector according to claim 5, wherein each cooling part comprises a plurality of horizontal cooling fins disposed at intervals on a surface of the outermost vertical cooling fins away from the support base; a plurality of horizontal cooling channels exists between the plurality of the horizontal cooling fins.

7. The electrical connector according to claim 5, wherein the support base comprises a first surface and a second surface; the first surface is opposite to the second surface; two ends of at least one of the plurality of vertical cooling fins are respectively away from the first surface and the second surface of the support base; the second heat sink is disposed on the first surface of the support base; the second surface is in contact with the upper surface of the electrical connector housing.

8. The electrical connector according to claim 7, wherein one of the vertical heat sink fins of each heat sink is in contact with a sidewall of the corresponding electrical connector housing.

9. The electrical connector according to claim 5, wherein the first heat sink comprises a plurality of securing grooves dividing the first heat sink into a plurality of sections; the quantity of the second heat sink is multiple; each second heat sink is disposed on the support base within each section; each second heat sink comprises a plurality of cooling channels.

10. The electrical connector according to claim 9, wherein the dimensions of each cooling channel of the second heat sink within each section is different.

11. The electrical connector according to claim 9, further comprising a securing component comprising a U-shaped securing part comprising a hollow part; the U-shaped securing part is disposed in the corresponding two securing grooves; the cooling parts and the second heat sinks in the two securing grooves are disposed in the hollow part; two ends of the U-shaped securing part are secured to two sidewalls of the electrical connector housing; the U-shaped securing part abuts against the support base.

12. The electrical connector according to claim 11, wherein each cooling part outside the hollow part further comprises a plurality of horizontal cooling fins disposed on a surface of the outermost vertical cooling fins away from the support base at intervals; a plurality of horizontal cooling channels exists in between the plurality of horizontal cooling fins.

13. The electrical connector according to claim 2, wherein the second heat sink comprises a plurality of U-shaped cooling fins stacked together;
the plurality of U-shaped cooling fins comprises a plurality of cooling channels.

14. The electrical connector according to claim 13, wherein the cooling channels of the second heat sink are provided with multiple dimensions.

15. The electrical connector according to claim 13, wherein each U-shaped cooling fins comprises a first plate and two opposite second plates; the two second plates are respectively disposed on two sides of the first plate; two second plates of each U-shaped cooling fins are connected to the first plate of the adjacent U-shaped cooling fin.

16. The electrical connector according to claim 4, further comprising a thermal conductive component disposed between the support base and the upper surface of the electrical connector housing.

17. The electrical connector according to claim 16, wherein an accommodating recess is provided on the surface facing the electrical connection housing of the support base; the thermal conductive component is disposed in the accommodating recess.

18. The electrical connector according to claim 17, wherein an opening is provided on the upper surface of the electrical connector housing; the thermal conductive component enters the electrical connector housing through the opening.

19. The electrical connector according to claim 18, wherein the thermal conductive component comprises a first thermal conductive part and a second thermal conductive part; the first thermal conductive part is disposed in the accommodating recess; the second thermal conductive part is disposed on the surface away from the support base of the first thermal conductive part; the second thermal conductive part is disposed in the electrical connector housing through the opening.
